(19) United States
(12) Patent Application Publication
(10) Pub. No.: US 2024/0165829 A1
(43) Pub. Date: May 23, 2024

(54) VACUUM SUCTION HEAD AND APPARATUS FOR TRANSFERRING SEMICONDUCTOR PRODUCT USING THE SAME

(71) Applicant: Samsung Electronics Co., Ltd., Suwon-si (KR)

(72) Inventors: Jong Min CHOI, Suwon-si (KR); Min-Su KANG, Suwon-si (KR); Nam Jin KIM, Suwon-si (KR); Dong Gun KIM, Suwon-si (KR); Han Byul SHIN, Suwon-si (KR); Hyun Seok YOON, Suwon-si (KR)

(73) Assignee: Samsung Electronics Co., Ltd., Suwon-si (KR)

(21) Appl. No.: 18/357,397

(22) Filed: Jul. 24, 2023

(30) Foreign Application Priority Data
Nov. 23, 2022 (KR) 10-2022-0158108

(51) Int. Cl. B25J 15/06; B25J 11/00

(52) U.S. Cl. CPC B25J 15/0683; B25J 11/0095

(57) ABSTRACT

A vacuum suction head may include a holder including a through hole formed therein, a suction pad surrounding at least a portion of a side surface of the holder, and a packing pad on a lower surface of the holder. The suction pad may protrude below a lower surface of the holder. The packing pad may include a cutout part. The cutout part may allow a space between the suction pad and the packing pad such that the space and the through hole may be in fluid communication with each other.

### CROSS-REFERENCE TO RELATED APPLICATION

This application claims priority from Korean Patent Application No. 10-2022-0158108 filed on Nov. 23, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a vacuum suction head and an apparatus for transferring a semiconductor product using the same.

### 2. Description of the Related Art

In order to transfer an electronic component having a small size, such as a semiconductor product (e.g., a solid-state drive (SSD)), a vacuum suction head that sucks a suction object using a vacuum pressure may be used. For example, a semiconductor product of which a manufacturing process has been completed may be decided as a good product or a defective product through a test process. An automated inspection apparatus may be used in such a test process. For example, the automated inspection apparatus may transfer a semiconductor product seated on a tray to a test area, perform a test by bringing input/output terminals of the semiconductor product into contact, classify the semiconductor product according to a test result, and then seat the semiconductor product on the tray. The transfer of the semiconductor product in the automated inspection apparatus may be performed by, for example, a picker on which a vacuum suction head is mounted. The picker may suck the semiconductor product to the vacuum suction head by providing a vacuum pressure to the vacuum suction head.

### SUMMARY

Aspects of the present disclosure provide a vacuum suction head capable of easily handling various suction objects.

Aspects of the present disclosure also provide an apparatus for transferring a semiconductor product capable of easily handling various suction objects.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a vacuum suction head may include a holder including a through hole formed therein; a suction pad surrounding at least a portion of a side surface of the holder, the suction pad protruding below a lower surface of the holder and having flexibility; and a packing pad on the lower surface of the holder. The packing pad may include a cutout part. The cutout part may allow a space between the suction pad and the packing pad such that the space and the through hole may be in fluid communication with each other.

According to an example embodiment of the present disclosure, a vacuum suction head may include a holder including a through hole formed therein; a packing pad on a lower surface of the holder, the packing pad having flexibility; and a suction pad surrounding a lower portion of the holder, the suction pad protruding below a lower surface of the packing pad and having flexibility. The through hole may extend in a vertical direction. In the vertical direction, a distance from the lower surface of the holder to a lowermost portion of the suction pad may be 0.5 mm to 2 mm. The packing pad may include a cutout part. The cutout part may extend in a horizontal direction. The horizontal direction may cross the vertical direction. The holder may further include an exhaust hole. The exhaust hole may penetrate through a sidewall of the holder and may be in fluid communication with the through hole. The exhaust hole may form an acute angle with the lower surface of the holder.

According to an example embodiment of the present disclosure, an apparatus may include a holder including a through hole; a picker configured to provide a vacuum pressure to the through hole, the picker having the holder installed thereon; a suction pad surrounding at least a portion of a side surface of the holder, the suction pad having flexibility and being configured to suck a semiconductor product; and a packing pad on a lower surface of the holder and having flexibility. The packing pad may include a cutout part. The cutout part may allow a space between the suction pad and the packing pad such that the space and the through hole may be in fluid communication with each other. A lower surface of the packing pad may be in contact with the semiconductor product when the semiconductor product is sucked to the suction pad.

### BRIEF DESCRIPTION OF THE DRAWINGS

The above and other aspects and features of the present disclosure will become more apparent by describing in detail example embodiments thereof with reference to the attached drawings, in which:

FIG. 1 is an illustrative exploded perspective view for describing a vacuum suction head according to some example embodiments.

FIG. 2 is a perspective view for describing the vacuum suction head of FIG. 1.

FIG. 3 is a cross-sectional view taken along line I-I of FIG. 2.

FIG. 4 is a view for describing a lower surface of the vacuum suction head of FIG. 1.

FIGS. 5 and 6 are various other views for describing a lower surface of a vacuum suction head according to some example embodiments.

FIGS. 7 and 8 are other various cross-sectional views for describing a vacuum suction head according to some example embodiments.

FIGS. 9 to 13 are intermediate operation drawings for describing the use of the vacuum suction head according to some example embodiments.

FIG. 14 is a schematic block diagram for describing an apparatus for transferring a semiconductor product using a vacuum suction head according to some example embodiments.

### DETAILED DESCRIPTION

The spatially relative terms “below”, “beneath”, “lower”, “above”, “upper”, and the like, as used herein may be used in order to easily describe correlations between one element or component and other elements or components as illustrated in the drawings. The spatially relative terms are to be understood as terms including different directions of elements at the time of being used or at the time of operating in addition to directions illustrated in the drawings. For example, when elements illustrated in the drawings are overturned, an element described as ‘below or beneath’ another element may be put ‘above’ another element. Accordingly, an illustrative term “below” may include both of a downward direction and an upward direction. Elements may be oriented in other directions as well, and accordingly, the spatially relative terms may be interpreted according to orientations.

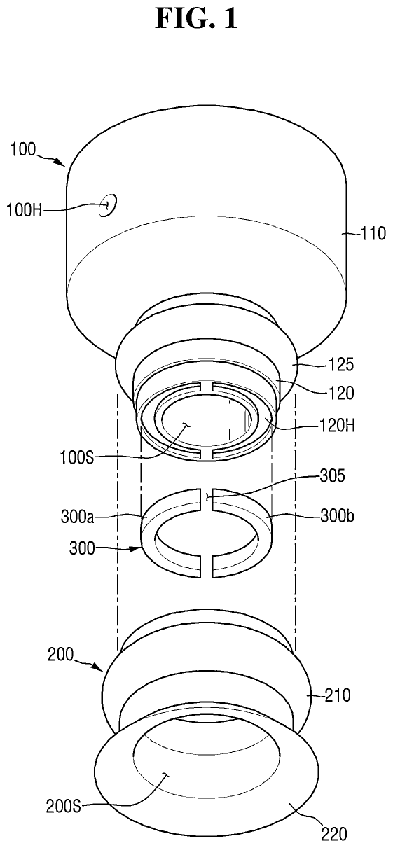

Hereinafter, a vacuum suction head according to example embodiments will be described with reference to FIGS. 1 to 8.

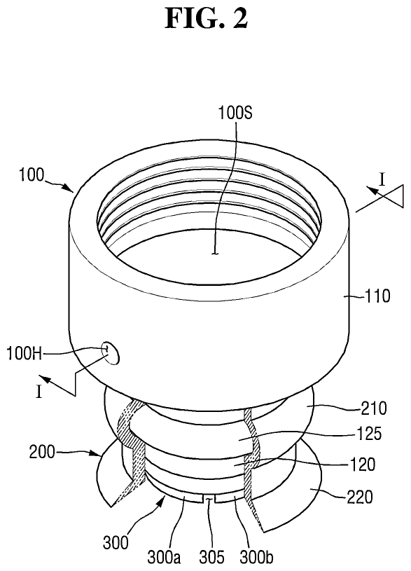

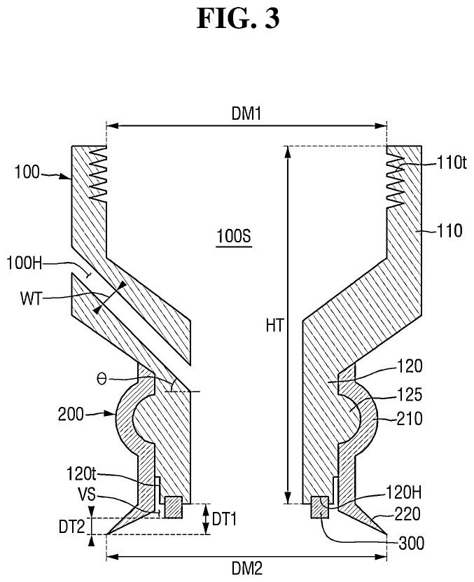

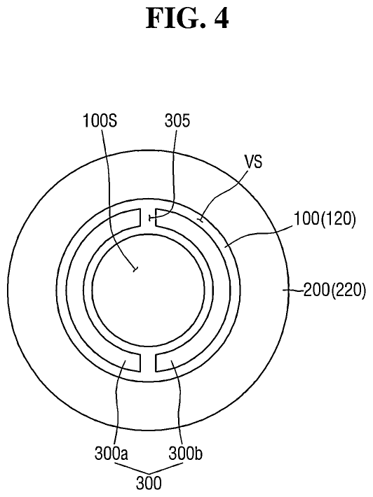

FIG. 1 is an illustrative exploded perspective view for describing a vacuum suction head according to some example embodiments. FIG. 2 is a perspective view for describing the vacuum suction head of FIG. 1. FIG. 3 is a cross-sectional view taken along line I-I of FIG. 2. FIG. 4 is a view for describing a lower surface of the vacuum suction head of FIG. 1.

Referring to FIGS. 1 to 4, a vacuum suction head according to some example embodiments includes a holder 100, a suction pad 200 and a packing pad 300.

The holder 100 may include a first through hole 100S formed therein. The first through hole 100S may extend from a lower surface of the holder 100 to an upper surface of the holder 100 to penetrate through an inner portion of the holder 100. In the following description, a direction in which the first through hole 100S extends may also be referred to as a vertical direction. For example, the holder 100 may be a cylindrical structure extending in the vertical direction as a whole. The holder 100 may be made of a metal material such as aluminum (Al), but is not limited thereto.

In some example embodiments, the holder 100 may include a body part 110 and protrusion part 120. The protrusion part 120 may protrude downward from a lower portion of the body part 110. A diameter of the protrusion part 120 may be smaller than a diameter of the body part 110. As an example, as illustrated in the drawings, the diameter of the protrusion part 120 may decrease and be then constant as the protrusion part 120 becomes distant from the body part 110.

The first through hole 100S may extend over the body part 110 and the protrusion part 120. In some example embodiments, a width of the first through hole 100S in the protrusion part 120 may be smaller than a width of the first through hole 100S in the body part 110. As an example, as illustrated in the drawings, the diameter of the first through hole 100S in the protrusion part 120 may decrease and be then constant as the first through hole 100S becomes distant from the body part 110.

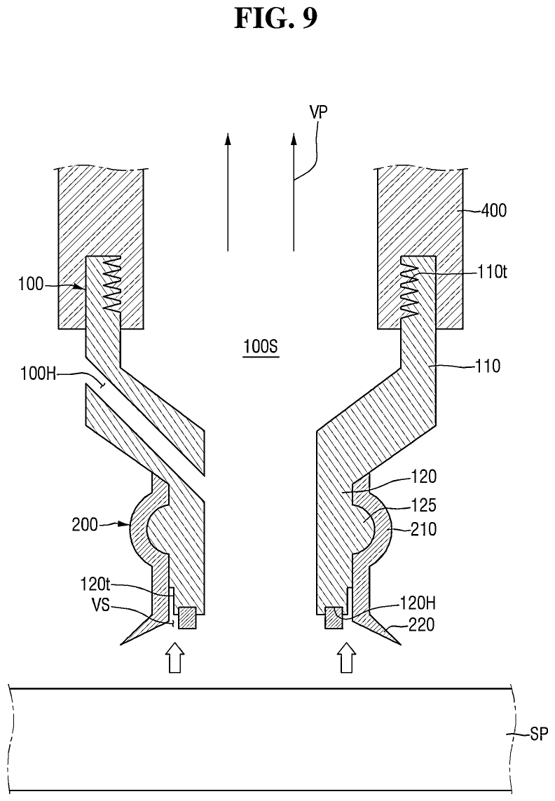

In some example embodiments, the holder 100 may further include an exhaust hole 100H. The exhaust hole 100H may penetrate through a sidewall of the holder 100 to communicate with the first through hole 100S. The exhaust hole 100H may be used to remove a vortex in the first through hole 100S when the suction of a suction object SP (see FIG. 9) is released. This will be described later in more detail in a description of FIGS. 9 to 13.

A width WT of the exhaust hole 100H may be, for example, about 0.1 mm to about 5 mm. In some embodiments, the width WT of the exhaust hole 100H may be about 0.5 mm to about 2 mm. Within this range, the exhaust hole 100H may efficiently remove the vortex in the first through hole 100S without excessively affecting a vacuum pressure provided to the first through hole 100S. In some example embodiments, the width WT of the exhaust hole 100H may be about 0.7 mm to about 1.5 mm.

In some example embodiments, the exhaust hole 100H may have an inclination. For example, the exhaust hole 100H may have an acute angle θ with respect to the lower surface of the holder 100. The acute angle θ formed between the lower surface of the holder 100 and the exhaust hole 100H may be, for example, about 10° to about 80°. In some embodiments, the acute angle θ formed between the lower surface of the holder 100 and the exhaust hole 100H may be about 30° to about 60°. In some example embodiments, the exhaust hole 100H may extend from a sidewall of the body part 110 to communicate with the first through hole 100S in the protrusion part 120.

In some example embodiments, an upper portion of the holder 100 may include a threaded groove 100t. For example, the threaded groove 100t may be formed on an inner side surface of the body part 110. The threaded groove 100t may be used to fasten the holder 100 to a picker 400 (see FIG. 9) on which the holder 100 is mounted.

In some example embodiments, a lower portion of the holder 100 may include a side groove 120t. The side groove 120t may be recessed and formed from an outer side surface of the holder 100. For example, the side groove 120t may be formed on an outer side surface of the protrusion part 120.

In the vertical direction, a length HT of the holder 100 may be, for example, about 10 mm to about 50 mm. In some embodiments, the length HT of the holder 100 may be about 15 mm to about 25 mm. In some example embodiments, the length HT of the holder 100 may be about 18 mm to about 19 mm.

On the upper surface of the holder 100, a diameter DM1 of the first through hole 100S (or an inner diameter of the holder 100) may be, for example, about 10 Φ to 50 Φ (or about 10 mm to about 50 mm). In some embodiments, the diameter DM1 of the first through hole 100S may be about 15 Φ to about 25 Φ. In some example embodiments, the diameter DM1 of the first through hole 100S may be about 18 Φ to about 22 Φ.

The suction pad 200 may be installed on the holder 100. For example, the suction pad 200 may include a second through hole 200S formed therein and communicating with the first through hole 100S. The second through hole 200S may accommodate at least a portion of the holder 100. Such a suction pad 200 may be fixed to the holder 100 by surrounding at least a portion of the holder 100 (e.g., a lower portion of the holder 100).

In addition, the suction pad 200 may protrude below the lower surface of the holder 100. For example, as illustrated in FIG. 3, the lowermost portion of the suction pad 200 may be disposed below a lower surface of the protrusion part 120 by DT1. The lower portion of the suction pad 200 may provide an area for sucking a suction object SP (see FIG. 9).

The suction pad 200 may have flexibility. For example, the suction pad 200 may include a flexible material such as rubber or soft plastic. The suction pad 200 may be elastically deformed to suck the suction object SP (see FIG. 9).

In some example embodiments, a surface resistance of the suction pad 200 may be about 10⁵ ohm/sq to about 10⁹ ohm/sq. Such a suction pad 200 may limit and/or prevent damage to the suction object SP (see FIG. 9) due to electrostatic discharge (ESD) by limiting and/or preventing charging of static electricity. As an example, the suction pad 200 may include acrylonitrile-butadiene rubber (NBR rubber). In some embodiments, the suction pad 200 may include hydrogenated acrylonitrile-butadiene rubber (HNBR rubber). The hydrogenated acrylonitrile-butadiene rubber has resistance to heat, ozone and chemicals and mechanical properties (abrasion resistance and physical properties, etc.) much more excellent than standard NBR rubber.

In some example embodiments, the suction pad 200 may include a fixed part 210 and a suction part 220.

The fixed part 210 may be fixed by surrounding the protrusion part 120 of the holder 100. For example, the holder 100 may further include a fixing projection 125 protruding from a side surface of the protrusion part 120. The fixed part 210 of the suction pad 200 may be formed to correspond to the fixing projection 125. Through this, when the protrusion part 120 of the holder 100 is accommodated in the second through hole 200S, the fixed part 210 may be engaged with and fixed to the fixing projection 125. In some example embodiments, a lower portion of the fixed part 210 may be spaced apart from the outer side surface of the protrusion part 120 by the side groove 120t.

The suction part 220 may extend downward from the lower portion of the fixed part 210. In some example embodiments, a diameter of the suction part 220 may increase as the suction part 220 becomes distant from the fixed part 210. For example, the suction part 220 may provide the second through hole 200S having a truncated cone shape. Such a suction part 220 may provide an area for coming into contact with the suction object SP (see FIG. 9).

At the lowermost portion of the suction part 220, an outer diameter DM2 of the suction part 220 may be, for example, about 10 Φ to about 50 Φ (or about 10 mm to about 50 mm). In some embodiments, the outer diameter (DM2) of the suction part 220 may be about 15 Φ to about 25 Φ. Such a suction part 220 may be suitable for sucking a relatively small and light suction object (e.g., a solid-state drive (SSD) product having a case form). In some example embodiments, the outer diameter DM2 of the suction part 220 may be about 18 Φ to about 22 Φ.

In the vertical direction, a distance DT1 from the lower surface of the holder 100 to the lowermost portion of the suction pad 200 may be about 2 mm or less. For example, the distance DT1 from the lower surface of the protrusion part 120 to the lowermost portion of the suction part 220 may be about 0.5 mm to about 2 mm. Within this range, the suction object SP (see FIG. 9) may be stably sucked to the suction pad 200. For example, when the distance DT1 from the lower surface of the protrusion part 120 to the lowermost portion of the suction part 220 exceeds 2 mm, there is a risk that the suction object SP (see FIG. 9) will fall due to an increase in shaking of the suction object SP in a process in which the suction object SP is sucked to the suction pad 200 and is transferred. In some embodiments, the distance DT1 from the lower surface of the protrusion part 120 to the lowermost portion of the suction part 220 may be about 1.0 mm to about 1.5 mm.

The packing pad 300 may be disposed on the lower surface of the holder 100. In addition, a lower surface of the packing pad 300 may be disposed lower than the lower surface of the holder 100. As an example, as illustrated in the drawings, the holder 100 may include a trench 120H recessed from the lower surface of the holder 100 (or the lower surface of the protrusion part 120). A portion of the packing pad 300 may be inserted into and fixed to the trench 120H. However, this is only an example, and the packing pad 300 may be disposed on the lower surface of the holder 100 by various other methods. As another example, unlike what is illustrated, the packing pad 300 may be disposed on the lower surface of the holder 100 by an adhesive layer or the like.

When the suction object SP (see FIG. 9) is sucked to the suction pad 200, the packing pad 300 may support the suction object. For example, the suction object may be in contact with the lower surface of the packing pad 300.

The packing pad 300 may have flexibility. For example, the packing pad 300 may include a flexible material such as rubber or soft plastic. Such a packing pad 300 may limit and/or prevent the suction object SP (see FIG. 9) from colliding with and being damaged by the holder 100.

In some example embodiments, a surface resistance of the packing pad 300 may be about 10⁵ ohm/sq to about 10⁹ ohm/sq. Such a packing pad 300 may limit and/or prevent damage to the suction object SP (see FIG. 9) due to electrostatic discharge (ESD) by limiting and/or preventing charging of static electricity. As an example, the packing pad 300 may include acrylonitrile-butadiene rubber (NBR rubber). In some embodiments, the packing pad 300 may include hydrogenated acrylonitrile-butadiene rubber (HNBR rubber). The hydrogenated acrylonitrile-butadiene rubber has resistance to heat, ozone and chemicals and mechanical properties (abrasion resistance and physical properties, etc.) more excellent than standard NBR rubber.

In some example embodiments, the suction pad 200 and the packing pad 300 may include the same material. As an example, each of the suction pad 200 and the packing pad 300 may include hydrogenated acrylonitrile-butadiene rubber.

In some example embodiments, the suction pad 200 may protrude below the lower surface of the packing pad 300. For example, as illustrated in FIG. 3, the lowermost portion of the suction part 220 may be disposed below the lower surface of the packing pad 300 by a distance DT2.

In the vertical direction, a distance DT2 from the lower surface of the packing pad 300 to the lowermost portion of the suction pad 200 may be about 1.5 mm or less. For example, the distance DT2 from the lower surface of the packing pad 300 to the lowermost portion of the suction pad 200 may be about 0.1 mm to about 1.5 mm. Within this range, the suction object SP (see FIG. 9) may be stably supported by the packing pad 300. For example, when the distance DT2 from the lower surface of the packing pad 300 to the lowermost portion of the suction pad 200 exceeds 1.5 mm, there is a risk that the suction object SP (see FIG. 9) will fall due to an increase in shaking of the suction object SP in the process in which the suction object SP is sucked to the suction pad 200 and is transferred. In some embodiments, the distance DT2 from the lower surface of the packing pad 300 to the lowermost portion of the suction pad 200 may be about 0.5 mm to about 1.0 mm.

In some example embodiments, the suction pad 200 may be spaced apart from a side surface of the packing pad 300. For example, a space VS may be defined between an inner side surface of the suction pad 200 and an outer side surface of the packing pad 300. In some example embodiments, the side groove 120t may be connected to the space VS between the suction pad 200 and the packing pad 300.

In some example embodiments, the packing pad 300 may include a cutout part 305. The cutout part 305 may allow the space VS between the suction pad 200 and the packing pad 300 and the first through hole 100S to communicate with each other. For example, as illustrated in FIG. 4, the cutout part 305 may extend in a horizontal direction crossing the vertical direction to cut the packing pad 300. The cutout part 305 may be used to remove a vortex in the space VS when the suction of the suction object SP (see FIG. 9) is released. This will be described later in more detail in a description of FIGS. 9 to 13.

In some example embodiments, the packing pad 300 may include a plurality of sub-pads (e.g., a first sub-pad 300a and a second sub-pad 300b) cut by the cutout part 305. It has been illustrated in FIG. 4 that the packing pad 300 is completely cut by the cutout part 305, but this is only an example. The cutout part 305 may also not completely cut the packing pad 300 as long as it allows the space VS between the suction pad 200 and the packing pad 300 and the first through hole 100S to communicate with each other. For example, unlike what is illustrated, a thickness of the packing pad 300 in which the cutout part 305 is formed may be smaller than a thickness of the packing pad 300 in which the cutout part 305 is not formed.

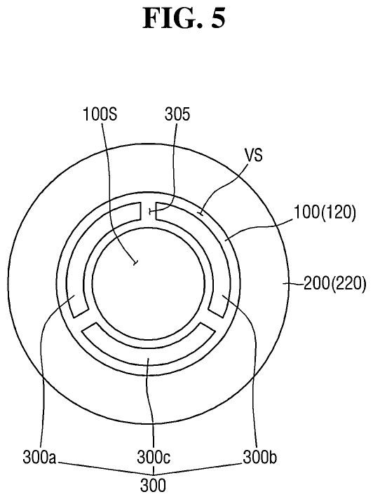

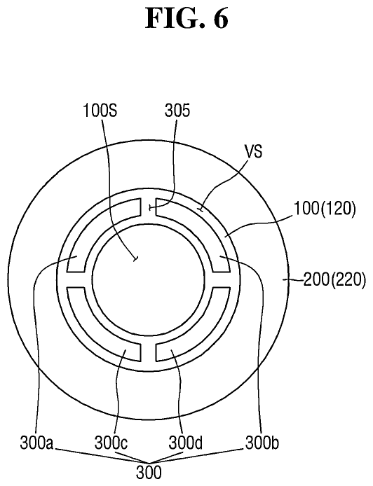

FIGS. 5 and 6 are various other views for describing a lower surface of a vacuum suction head according to some example embodiments. For convenience of explanation, portions overlapping those described above with reference to FIGS. 1 to 4 will be briefly described or a description thereof will be omitted.

Referring to FIG. 5, in a vacuum suction head according to some example embodiments, a packing pad 300 may include three cutout parts 305.

For example, the packing pad 300 may include three sub-pads (e.g., a first sub-pad 300a, a second sub-pad 300b, and a third sub-pad 300c) cut by the three cutout parts 305.

Referring to FIG. 6, in a vacuum suction head according to some example embodiments, a packing pad 300 may include four cutout parts 305.

For example, the packing pad 300 may include four sub-pads (e.g., a first sub-pad 300a, a second sub-pad 300b, a third sub-pad 300c, and a fourth sub-pad 300d) cut by the four cutout parts 305.

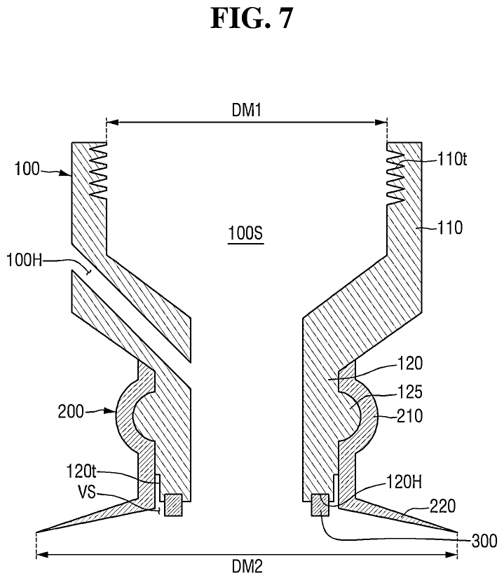

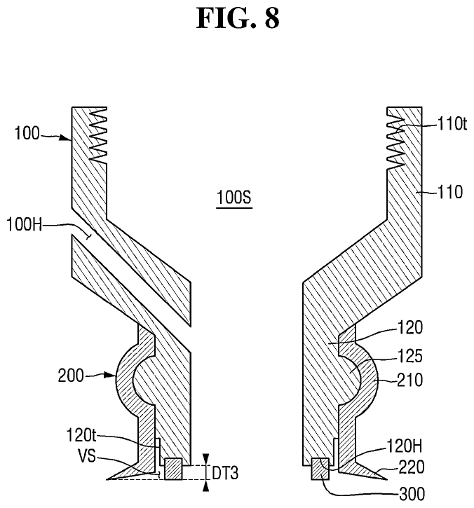

FIGS. 7 and 8 are other various cross-sectional views for describing a vacuum suction head according to some example embodiments. For convenience of explanation, portions overlapping those described above with reference to FIGS. 1 to 6 will be briefly described or a description thereof will be omitted.

Referring to FIG. 7, in a vacuum suction head according to some example embodiments, the outer diameter DM2 of the suction part 220 may be greater than the diameter DM1 of the first through hole 100S.

For example, the diameter DM1 of the first through hole 100S may be about 10 Φ to about 50 Φ, and the outer diameter DM2 of the suction part 220 may be greater than the diameter DM1 of the first through hole 100S. Such a suction part 220 may be suitable for sucking a relatively great and heavy suction object (e.g., an SSD product having a printed circuit board (PCB) form). In some embodiments, the diameter DM1 of the first through hole 100S may be about 15 Φ to about 25 Φ, and the outer diameter DM2 of the suction part 220 may be about 25 Φ to about 35 Φ. In some example embodiments, the diameter DM1 of the first through hole 100S may be about 18 Φ to about 22 Φ, and the outer diameter DM2 of the suction part 220 may be about 28 Φ to about 32Φ.

Referring to FIG. 8, in the vacuum suction head according to some example embodiments, the lowermost portion of the suction pad 200 may be disposed coplanar with the lower surface of the packing pad 300.

For example, the suction pad 200 may not protrude below the lower surface of the packing pad 300. In the vertical direction, a distance DT3 from the lower surface of the holder 100 to the lowermost portion of the suction pad 200 may be about 1.5 mm or less. For example, the distance DT3 from the lower surface of the protrusion part 120 to the lowermost portion of the suction pad 200 may be about 0.1 mm to about 1.5 mm. In some embodiments, the distance DT3 from the lower surface of the protrusion part 120 to the lowermost portion of the suction pad 200 may be about 0.5 mm to about 1.0 mm.

Hereinafter, the use of the vacuum suction head according to example embodiments will be described with reference to FIGS. 1 to 13.

FIGS. 9 to 13 are intermediate operation drawings for describing the use of the vacuum suction head according to some example embodiments. For convenience of explanation, portions overlapping those described above with reference to FIGS. 1 to 8 will be briefly described or a description thereof will be omitted.

Referring to FIG. 9, the vacuum suction head according to some example embodiments is disposed on a suction object SP.

For example, a vacuum suction head according to some example embodiments may be mounted on a picker 400. For example, the holder 100 may be mounted on the picker 400 through the threaded groove 100t. For example, the picker 400 may be horizontally moved to provide the holder 100 to the suction object SP.

In some example embodiments, the suction object SP may include various semiconductor products such as a memory and a module. As an example, the suction object SP may include a solid-state drive (SSD) product. The suction object SP may be a relatively small and light semiconductor product such as an SSD product having a case form or a relatively great and heavy semiconductor product such as an SSD product having a printed circuit board (PCB) form.

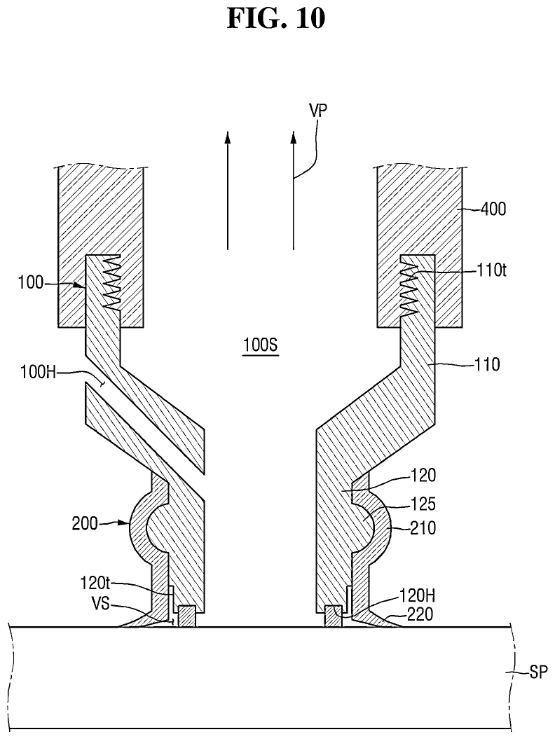

Referring to FIGS. 9 and 10, a vacuum pressure VP is provided to the first through hole 100S.

For example, the picker 400 may provide the vacuum pressure VP to the first through hole 100S. For example, the picker 400 may include a device that provides vacuum pressure (VP) using a Coanda effect. As the vacuum pressure VP is provided to the first through hole 100S, the suction object SP may be sucked to the suction pad 200. The suction pad 200 may be elastically deformed to suck the suction object SP.

When the suction object SP is sucked to the suction pad 200, the packing pad 300 may support the suction object SP. For example, the suction object SP may be in contact with the lower surface of the packing pad 300. Such a packing pad 300 may limit and/or prevent the suction object SP from colliding with and being damaged by the holder 100.

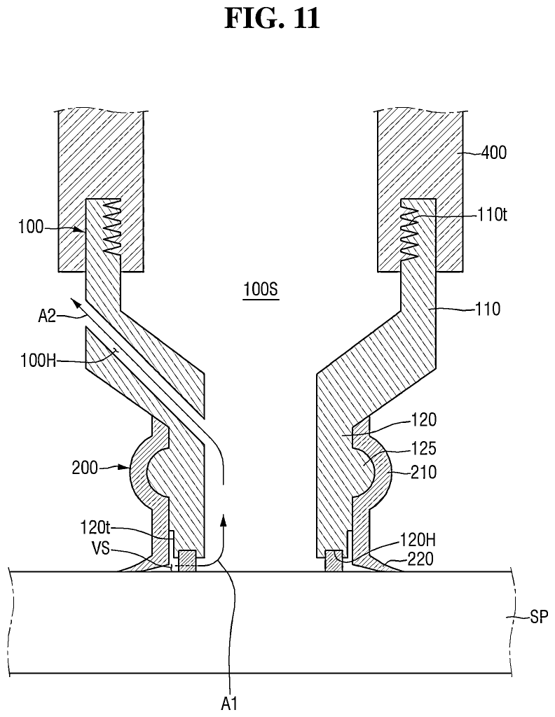

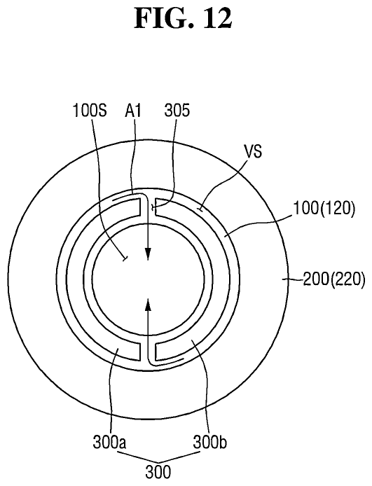

Referring to FIGS. 11 and 12, the vacuum pressure VP provided to the first through hole 100S is released to release the suction of the suction object SP.

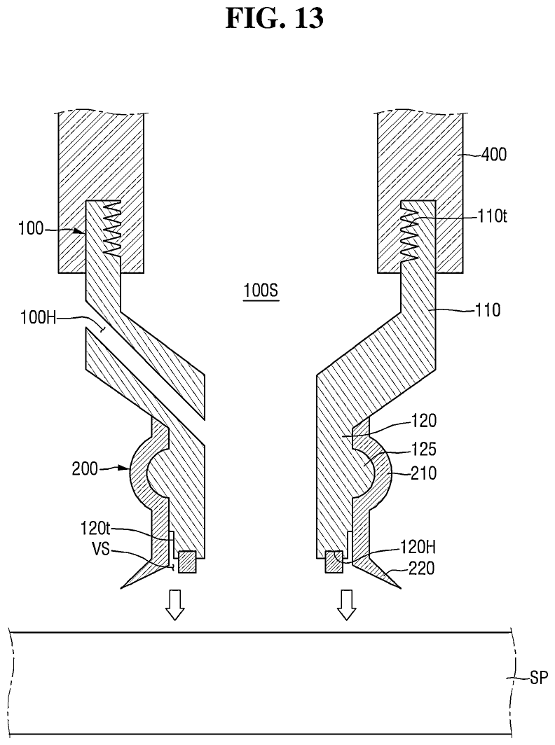

For example, the picker 400 may stop providing the vacuum pressure VP to the first through hole 100S. When the vacuum pressure VP is released, a vortex generated at a lower portion of the suction pad 200 may hinder the suction object SP from being separated from the suction pad 200. However, the vacuum suction head according to some example embodiments may easily remove the vortex using the cutout part 305 and/or the exhaust hole 100H. Specifically, the vortex generated in the space VS between the suction pad 200 and the packing pad 300 may be easily removed through the cutout part 305 connected to the first through hole 100S (A1). In addition, the vortex generated at the lower portion of the suction pad 200 may be easily removed through the exhaust hole 100H (A2). Accordingly, the suction between the suction pad 200 and the suction object SP may be easily released. As depicted in FIG. 13, the suction object SP may be spaced apart from the vacuum suction head after the vacuum pressure VP is released. For example, the suction object SP may be spaced apart from the suction pad 200 after the vacuum pressure VP is released.

Due to the diversification of semiconductor products, frequent replacement of a vacuum suction head may be required according to sizes, weights, and the like, of the semiconductor products. For example, a relatively small (e.g., about 20 Φ) suction pad may be required for a relatively small and light suction object (e.g., an SSD product having a case form), and a relatively great (e.g., about 30 Φ) suction pad may be required for a relatively great and heavy suction object (e.g., an SSD product having a printed circuit board (PCB) form). However, such frequent replacement of the vacuum suction head increases process time and requires management of components, which causes a decrease in productivity.

However, the vacuum suction head according to some example embodiments may stably suck the suction object SP by a double lip structure of the suction pad 200 and the packing pad 300. Specifically, as described above, the suction pad 200 may protrude from the lower surface of the holder 100 by about 2 mm or less to limit and/or minimize shaking of the suction object SP. In addition, when the suction object SP is sucked to the suction pad 200, the packing pad 300 may stably support the suction object SP. Accordingly, a vacuum suction head capable of easily handling various suction objects without replacing the suction pad 200 may be provided.

Hereinafter, an apparatus for transferring a semiconductor product using a vacuum suction head according to example embodiments will be described with reference to FIGS. 1 to 14.

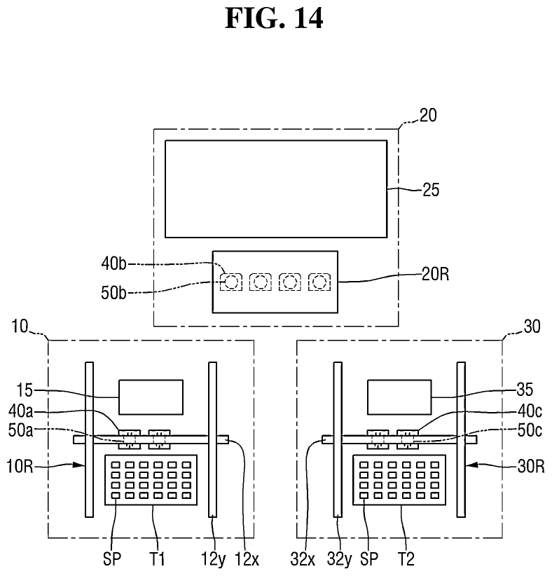

FIG. 14 is a schematic block diagram for describing an apparatus for transferring a semiconductor product using a vacuum suction head according to some example embodiments. For convenience of explanation, portions overlapping those described above with reference to FIGS. 1 to 13 will be briefly described or a description thereof will be omitted.

Referring to FIG. 14, an apparatus for transferring a semiconductor product according to some example embodiments includes a loading unit 10, a testing unit 20 and an unloading unit 30.

The loading unit 10 may transfer the suction object SP (e.g., a semiconductor product) provided to the loading unit 10 to the testing unit 20. For example, the loading unit 10 may include a loading robot 10R. The loading robot 10R may provide a first picker 40a on which a first vacuum suction head 50a is installed. The first vacuum suction head 50a may be the vacuum suction head described above with reference to FIGS. 1 to 8. The loading robot 10R may transfer the suction object SP seated on a first tray T1 to a first buffer area 15 using the first vacuum suction head 50a and the first picker 40a. For example, the first vacuum suction head 50a may suck the suction object SP by receiving a vacuum pressure provided from the first picker 40a, and the first picker 40a may be configured to be movable by a first rail 12x and a second rail 12y crossing each other.

The testing unit 20 may perform a test process on the suction object SP provided to a test area 25. For example, the testing unit 20 may include a testing robot 20R. The testing robot 20R may provide a second picker 40b on which a second vacuum suction head 50b is installed. The second vacuum suction head 50b may be the vacuum suction head described above with reference to FIGS. 1 to 8.

The testing robot 20R may transfer the suction object SP seated on the first buffer area 15 to the test area 25 using the second vacuum suction head 50b and the second picker 40b. For example, the second vacuum suction head 50b may suck the suction object SP on the first buffer area 15 by receiving a vacuum pressure provided from the second picker 40b, and the second picker 40b may be configured to be movable between the first buffer area 15 and the test area 25.

In addition, the testing robot 20R may classify the suction object SP according to a result of the test process and transfer the classified suction object SP to a second buffer area 35. For example, the second vacuum suction head 50b may suck the suction object SP on the test area 25 by receiving a vacuum pressure provided from the second picker 40b, and the second picker 40b may be configured to be movable between the test area 25 and the second buffer area 35.

The unloading unit 30 may transfer the suction object SP provided to the second buffer area 35 to a second tray T2. For example, the unloading unit 30 may include an unloading robot 30R. The unloading robot 30R may provide a third picker 40c on which a third vacuum suction head 50c is installed. The third vacuum suction head 50c may be the vacuum suction head described above with reference to FIGS. 1 to 8. The unloading robot 30R may transfer the suction object SP seated on the second buffer area 35 to the second tray T2 using the third vacuum suction head 50c and the third picker 40c. For example, the third vacuum suction head 50c may suck the suction object SP by receiving a vacuum pressure provided from the third picker 40c, and the third picker 40c may be configured to be movable by a third rail 32x and a fourth rail 32y crossing each other.

Through this, an apparatus for transferring a semiconductor product capable of easily handling various suction objects may be provided.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A vacuum suction head comprising:
a holder including a through hole formed therein;
a suction pad surrounding at least a portion of a side surface of the holder,
the suction pad protruding below a lower surface of the holder and having flexibility; and
a packing pad on the lower surface of the holder, wherein
the packing pad includes a cutout part, and
the cutout part allows a space between the suction pad and the packing pad such that the space and the through hole are in fluid communication with each other.

2. The vacuum suction head of claim 1, wherein
the through hole extends in a vertical direction, and
in the vertical direction, a distance from the lower surface of the holder to a lowermost portion of the suction pad is 0.5 mm to 2 mm.

3. The vacuum suction head of claim 1, wherein a lowermost portion of the suction pad protrudes below a lower surface of the packing pad.

4. The vacuum suction head of claim 3, wherein
the through hole extends in a vertical direction, and
in the vertical direction, a distance from the lower surface of the packing pad to the lowermost portion of the suction pad is 1 mm or less.

5. The vacuum suction head of claim 1, wherein
the holder further includes an exhaust hole,
the exhaust hole penetrates through a sidewall of the holder and is in fluid communication with the through hole.

6. The vacuum suction head of claim 5, wherein the exhaust hole forms an acute angle with the lower surface of the holder.

7. The vacuum suction head of claim 5, wherein a width of the exhaust hole is 0.5 mm to 2 mm.

8. The vacuum suction head of claim 1, wherein an outer diameter of a lowermost portion of the suction pad is 15 mm to 25 mm.

9. The vacuum suction head of claim 1, wherein
the suction pad is configured to suck a suction object using a vacuum pressure provided to the through hole, and
when the suction object is sucked to the suction pad, a lower surface of the packing pad is in contact with the suction object.

10. A vacuum suction head comprising:
a holder including a through hole formed therein;
a packing pad on a lower surface of the holder, the packing pad having flexibility; and
a suction pad surrounding a lower portion of the holder, the suction pad protruding below a lower surface of the packing pad and having flexibility, wherein
the through hole extends in a vertical direction,
in the vertical direction, a distance from the lower surface of the holder to a lowermost portion of the suction pad is 0.5 mm to 2 mm,
the packing pad includes a cutout part,
the cutout part extends in a horizontal direction,
the horizontal direction crosses the vertical direction,
the holder further includes an exhaust hole,
the exhaust hole penetrates through a sidewall of the holder and is in fluid communication with the through hole, and
the exhaust hole forms an acute angle with the lower surface of the holder.

11. The vacuum suction head of claim 10, wherein
in the vertical direction, a length of the holder is 15 mm to 25 mm.

12. The vacuum suction head of claim 10, wherein
on an upper surface of the holder, a diameter of the through hole is 15 mm to 25 mm.

13. The vacuum suction head of claim 10, wherein
a width of the exhaust hole is 0.5 mm to 2 mm.

14. The vacuum suction head of claim 10, wherein
an outer diameter of a lowermost portion of the suction pad is 15 mm to 25 mm.

15. The vacuum suction head of claim 10, wherein
the holder includes a trench recessed from the lower surface of the holder, and
a portion of the packing pad is in the trench.

16. The vacuum suction head of claim 10, wherein a surface resistance of each of the suction pad and the packing pad is 10⁵ ohm/sq to 10⁹ ohm/sq.

17. The vacuum suction head of claim 16, wherein the suction pad and the packing pad each include hydrogenated acrylonitrile butadiene rubber (HNBR).

18. An apparatus for transferring a semiconductor product, comprising:
a holder including a through hole;
a picker configured to provide a vacuum pressure to the through hole, the picker having the holder installed thereon;
a suction pad surrounding at least a portion of a side surface of the holder,
the suction pad having flexibility and being configured to suck a semiconductor product; and
a packing pad on a lower surface of the holder and having flexibility, wherein
the packing pad includes a cutout part,
the cutout part allows a space between the suction pad and the packing pad such that the space and the through hole are in fluid communication with each other, and
a lower surface of the packing pad is in contact with the semiconductor product when the semiconductor product is sucked to the suction pad.

19. The apparatus for transferring a semiconductor product of claim 18, wherein the semiconductor product includes a solid-state drive (SSD).

20. The apparatus for transferring a semiconductor product of claim 18, wherein the picker is configured to provide the vacuum pressure using a Coanda effect.
